(19) United States
(12) Patent Application Publication
(10) Pub. No.: US 2015/0155328 A1
(43) Pub. Date: Jun. 4, 2015

(54) IMAGE SENSOR

(71) Applicant: Samsung Electronics Co., Ltd., Suwon-Si (KR)

(72) Inventors: Hae-Yong PARK, Bucheon-si (KR); Kyung-Ho LEE, Suwon-si (KR); Jung-Chak AHN, Yongin-si (KR); Sang-Jun CHOI, Seoul (KR)

(21) Appl. No.: 14/515,835

(22) Filed: Oct. 16, 2014

(30) Foreign Application Priority Data
Nov. 29, 2013 (KR) 10-2013-0147185

(51) Int. Cl. H01L 27/146; H04N 5/378

(52) U.S. Cl. CPC H01L 27/14645; H01L 27/14612; H01L 27/14621; H01L 27/14627; H04N 5/378

(57) ABSTRACT

In an image sensor, a photoelectric convertor is arranged in an active region of substrate and a floating diffusion area is arranged over the photoelectric convertor. A transfer transistor transfers the photo charges to the floating diffusion area from the photoelectric convertor and the transfer gate electrode has a narrow upper structure that extends downwards vertically from the top surface of the substrate and a broad lower structure that is connected to the upper structure and has a width greater than a width of the upper structure. A reading device is on the top surface of the substrate and detects the photo charges from the floating diffusion area. Accordingly, the effective gate length of the transfer gate electrode is increased, and thus, high resolution image data can be obtained in spite of the size reduction of the image sensor.

### CROSS-REFERENCE TO RELATED APPLICATIONS

This application claims the benefit of Korean Patent Application No. 10-2013-0147185 filed on Nov. 29, 2013 in the Korean Intellectual Property Office, the disclosure of which is incorporated herein in its entirety by reference.

### BACKGROUND

1. Field

Example embodiments relate to an image sensor, such as a back-side illuminated (BSI) complementary metal oxide semiconductor (CMOS) image sensor.

2. Description of the Related Art

An image sensor is a device that transforms incident light into electrical signals and generates image signals corresponding to the electrical signals. As computer and communication industries has been rapidly developed, the image sensor has been widely used for various devices such as a digital camera, a digital camcorder, a mobile phone, a security camera and an endoscopic camera.

Particularly, an image sensor using a complementary metal-oxide semiconductor (CMOS) chip (hereinafter, CMOS image sensor (CIS)) has a simple driving mechanism and a downsized structure in which an analogue signal processing circuit and a digital signal processing circuit are integrated into a single chip. Thus, the CIS usually works well with a battery having a small size and capacity. For those reasons, the CIS has been widely used as an image sensor for a mobile system and a small-sized electronic system.

Recently, so as to improve light guiding efficiency and photosensitivity, the CIS tends to be configured as a back-side illuminated (BSI) image sensor in which the incident light reaches a photodiode of the CIS from the back side or a rear surface of a semiconductor substrate. Most of the conventional BSI image sensors include a vertical transfer gate for improving transfer efficiency of photo charges. In the conventional BSI image sensors, the transfer gate of the image sensor is usually arranged on a front side or a front surface of the semiconductor substrate and extends vertically into an inside of the substrate toward a photo charge collector, so that the gap distance between the vertically extended transfer gate (vertical transfer gate, VTG) and the photo charge collector is reduced.

### SUMMARY

Some example embodiments of inventive concepts provide an image sensor including a vertical transfer gate of which the effective channel length is sufficient, thereby improving the transfer efficiency of the photo charges.

According to some example embodiments, there is provided an image sensor including a photoelectric convertor in an active region of a substrate, the photoelectric converter configured to generate photo charges corresponding to incident light, a floating diffusion area over the photoelectric convertor and adjacent to a first surface of the substrate, a transfer transistor having a transfer gate structure, the transfer transistor is configured to transfer the photo charges to the floating diffusion area from the photoelectric convertor, and a reading device on the first surface of the substrate. The floating diffusion area is configured to receive the photo charges. The transfer gate structure may have a narrow upper structure and a broad lower structure, the upper structure extending from the first surface of the substrate to the lower structure, the lower structure having a width greater than a width of the upper structure. The reading device may detect the photo charges from the floating diffusion area and may output electrical signals corresponding to the photo charges.

In an example embodiment, the photoelectric convertor may include a first doping layer having a first plurality of n-type dopants and a second doping layer having a first plurality of p-type dopants, and the floating diffusion area may include a second plurality of n-type dopants.

In an example embodiment, the first doping layer may include a first low concentration layer and a first high concentration layer, the first high concentration layer having a higher concentration of n-type dopants than the first low concentration layer. The second doping layer may include a second low concentration layer and a second high concentration layer, the second high concentration layer having a higher concentration of p-type dopants than the second lower concentration layer.

In an example embodiment, the upper structure may be adjacent to the floating diffusion area and the lower structure may be connected to the photoelectric convertor.

In an example embodiment, the lower structure may be one of a spherical flask shape and an Erlenmeyer flask shape.

In an example embodiment, a top surface of the vertical transfer gate structure may be coplanar with the first surface of the substrate and buried in the substrate.

In an example embodiment, the image sensor may further include a local doping layer in the substrate. The local doping layer may enclose the transfer gate structure, the local doping layer having a second plurality of p-type dopants, and the local doping layer having a higher concentration of p-type dopants than the second doping layer.

In an example embodiment, the active region of the substrate may include a first region and a second region, the first region including the photoelectric convertor and the transfer transistor, the second region being adjacent to the first region, at least a portion of the reading device being in the second region.

In an example embodiment, the reading device may include a reset transistor configured to discharge the floating diffusion area, an output transistor configured to amplify a voltage of the floating diffusion area and output the amplified voltage as an output voltage of a unit pixel and a selection transistor configured to select the unit pixel in response to a selection signal and transfer the output voltage. One of the reset, the output and the selection transistors may be in the first region and the remaining transistors of the reading device may be in the second region.

In an example embodiment, the image sensor may further include a rear doping layer having a plurality of p-type dopants, the rear doping layer being adjacent to a second surface opposite to the first surface of the substrate.

In an example embodiment, the image sensor may further include a light transmittance unit on the second surface of the substrate and the light transmittance unit corresponds to the photoelectric convertor. The light transmittance unit may be configured to focus the incident light to the photoelectric convertor.

In an example embodiment, the light transmittance unit may include a micro lens configured to focus the incident light to the photoelectric convertor and a color filter under the micro lens.

According to some example embodiments, there is provided another image sensor including a pixel array having a plurality of unit pixels in a matrix, the unit pixels configured to generate electrical signals from incident light, a first signal unit configured to apply a driving signal to each of the unit pixels in the pixel array through a plurality of row lines of the matrix, a second signal unit configured to detect the electrical signals of each unit pixel through a plurality of column lines of the matrix, and a timing signal generator configured to generate a timing signal for selectively controlling the row lines and the column lines. In the above image sensor, at least one of the unit pixels may include a photoelectric convertor in an active region of a semiconductor substrate, the photoelectric converter is configured to generate photo charges corresponding to incident light, a floating diffusion area over the photoelectric convertor and adjacent to a first surface of the substrate, a transfer transistor having a transfer gate structure, the transfer transistor configured to transfer the photo charges to the floating diffusion area from the photoelectric convertor, and a reading device on the first surface of the substrate. The floating diffusion area is configured receive the photo charges. The transfer gate structure may have a narrow upper structure and a broad lower structure, the upper structure extending from the first surface of the substrate to the lower structure, the lower structure having a width greater than a width of the upper structure. The reading device is configured to detect the photo charges from the floating diffusion area and may output electrical signals corresponding to the photo charges.

In an example embodiment, the first signal unit may include a row decoder and a row driver, and the second signal unit includes a column decoder, a correlated double sampler and an analogue-to-digital converter (ADC).

In an example embodiment, the image sensor may further include a buffer unit configured to receive a plurality of image signals corresponding to the electrical signals of the unit pixels and processing the image signals in a decoding sequence of the column decoder.

At least one example embodiment discloses an image sensor including a substrate, a photoelectric converter in the substrate, the photoelectric converter configured to generate charges based on incident light and a transfer transistor configured to transfer the generated charges, the transfer transistor having a transfer gate structure, the transfer gate structure including an upper portion and a lower portion, the upper portion extending from an upper surface of the substrate to the lower portion in a direction towards a lower surface of the substrate, a width of the lower portion being greater than a width of the upper portion.

In an example embodiment, the photoelectric converter includes a first doping layer and a second doping layer, the second doping layer including a first concentration layer and a second concentration layer, a concentration of first-type dopants in the second concentration layer being higher than a concentration of first-type dopants in the first concentration layer, the second concentration layer being between the first concentration layer and the upper surface of the substrate.

In an example embodiment, the first doping layer includes a third concentration layer and a fourth concentration layer, a concentration of second-type dopants in the fourth concentration layer being higher than a concentration of second-type dopants in the third concentration layer, the third concentration layer being between the fourth concentration layer and the lower surface of the substrate.

In an example embodiment, the first-type dopants are p-type dopants and the second-type dopants are n-type dopants.

In an example embodiment, the image sensor further includes a floating diffusion area in the substrate, on the photoelectric converter and adjacent to the upper surface of the substrate, the floating diffusion area configured to receive the generated charges from the transfer transistor and a read device configured to output the charges received by the floating diffusion area.

According to example embodiments of present inventive concepts, the upper portion of the transfer gate structure may be downsized in view of the size reduction of the image sensor. However, the lower portion of the transfer gate structure, which may be connected to the photoelectric convertor, may be upsized in spite of the size reduction of the image sensor. Therefore, although the active region and the unit pixel may be downsized so as to increase the degree of integration of the image sensor, the lower portion of the transfer gate structure may be upsized or at least maintained without any size reduction, thereby preventing the short channel effect at the transfer gate structure in spite of the size reduction of the unit pixel. As a result, although the size of the image sensor may be reduced and the degree of integration of the images sensor may be increased, the transfer efficiency of the transfer transistor may not be deteriorated to thereby prevent the after-images of the image sensor.

### BRIEF DESCRIPTION OF THE DRAWINGS

Example embodiments will be more clearly understood from the following detailed description taken in conjunction with the accompanying drawings.

FIG. 1 is a structural view illustrating an image sensor in accordance with an example embodiment of inventive concepts;

FIG. 2 is a circuit diagram showing a pixel array of the image sensor illustrated in FIG. 1 in accordance with an example embodiment of inventive concepts;

FIG. 3A is a plan view illustrating a unit pixel of the image sensor shown in FIG. 1;

FIG. 3B is a cross sectional view cut along a line I-I′ of the unit pixel shown in FIG. 3A;

FIGS. 4A to 4C are cross-sectional views illustrating modified transfer gate structures of the unit pixel shown in FIG. 3B in accordance with an example embodiment of inventive concepts;

FIGS. 5A to 5H are cross sectional views illustrating processing steps for a method of manufacturing the image sensor shown in FIGS. 1, 3A and 3B;

FIG. 6 is a block diagram showing an imaging apparatus including the image sensor shown in FIG. 1 in accordance with an example embodiment of inventive concepts; and

FIG. 7 is a perspective view illustrating an electronic system including the imaging apparatus shown in FIG. 6 in accordance with an example embodiment of inventive concepts.

### DETAILED DESCRIPTION OF EXAMPLE EMBODIMENTS

Various example embodiments will be described more fully hereinafter with reference to the accompanying drawings, in which some example embodiments are shown. Example embodiments may, however, be embodied in many different forms and should not be construed as limited to the example embodiments set forth herein. Rather, example embodiments are provided so that this disclosure will be thorough and complete, and will fully convey the scope of inventive concepts to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of inventive concepts.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which inventive concepts belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

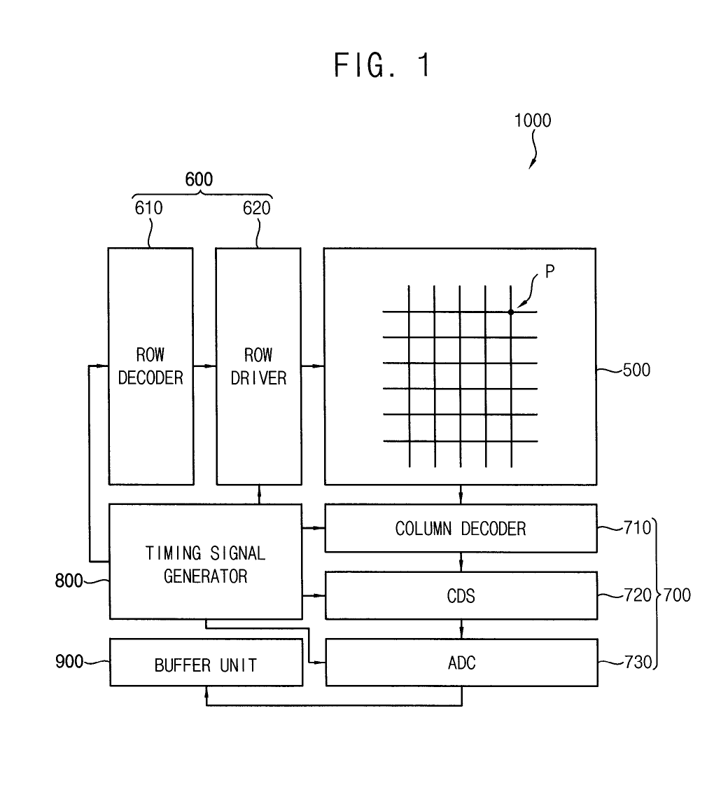

FIG. 1 is a structural view illustrating an image sensor in accordance with an example embodiment of inventive concepts. A CIS is illustrated in FIG. 1 as the image sensor.

Referring to FIG. 1, an image sensor 1000 may include a pixel array 500 having a plurality of unit pixels P in a matrix and configured to generate electrical signals from incident light, a first signal unit 600 configured to apply a driving signal to each of the unit pixels P in the pixel array 500 through a plurality of row lines of the matrix, a second signal unit 700 configured to detect an image signal from the electrical signals of each unit pixel P through a plurality of column lines of the matrix and a timing signal generator 800 configured to generate a timing signal for selectively controlling the row lines to which the driving signals may be applied and the column lines from which the image signals may be detected. The image sensor 1000 may further include a buffer unit in which a plurality of the image signals may be received and processed in a decoding sequence of a column decoder of the second signal unit 700. The first signal unit 600 may include a row decoder 610 and a row driver 620 and the second signal unit 700 includes a column decoder 710, a correlated double sampler 720 and an analogue-to-digital converter (ADC) 730.

For example, the pixel array 500 may include a plurality of the unit pixels P that is arranged in a two-dimensional matrix having a plurality of the row lines and the column lines. That is, each unit pixel P may be positioned at a cross point of a single row line and a single column. In each of the unit pixels of the pixel array 500, an electrical signal may be generated in response to the light that may be incident onto the pixel array 500. A plurality of driving signals such as a pixel selection signal, a reset signal and a charge transfer signal may be applied to the pixel array 500 by the first signal unit 600. In addition, the electrical signals of the unit pixels P of the pixel array 500 may be detected by the second signal unit 700.

The first signal unit 600 may apply the driving signals to each of the unit pixels P in the pixel array 500. For example, the first signal unit 600 may include a row decoder 610 and a row driver 620 connected to the row decoder 610. The row decoder 610 may select at least one of the row lines of the pixel array 500 and the row driver 620 may apply the driving signals to the selected row lines of the pixel array 500. Therefore, when the driving signals may be applied to the pixel array 500, a series of the unit pixels P that may be connected to the selected row line may be simultaneously driven by the driving signals.

The second signal unit 700 may detect the electrical signal of the unit pixel P. For example, the second signal unit 700 may include a column decoder 710 that may select the column line through which the electrical signal of the unit pixel P is detected, a correlated double sampler (CDS), 720 for sampling the electrical signals from the unit pixel P connected to the column line and an analogue-to-digital converter (ADC), 730 for converting an analogue signal of the electrical signal of the unit pixel P to a digital signal. The CDS 720 may detect a particular noise level and a signal level corresponding to the electrical signal of the unit pixel P and may obtain the level difference between the noise level and the signal level by using capacitors and switches. Then, the CDS 720 may output the level difference as an analogue effective signal of the electrical signal at the unit pixel P. The level difference may be output at every column line of the pixel array 500 by the CDS 720. The analogue effective signal may be converted into a digital signal by the ADC 730.

The timing signal generator 800 may be electrically connected to both of the first and the second signal units 600 and 700, and various timing signals may be applied to the row decoder 610 and the column decoder 710 by the timing signal generator 800. The timing signals may select at least one of the row lines to which the driving signal may be applied (driving row line) and may control the time when the driving signal may be applied to the driving row line. In addition, the timing signals may also select at least one of the column lines through which the electrical signal of the unit pixel P may be detected (detecting column line) and may control the time when the electrical signal may be detected from the detecting column line.

The electrical signals of the unit pixels P may be transferred to the buffer unit 900 from the second signal unit 700 and may be received in the buffer unit 900 as the digital signal of each unit pixel P. Then, the digital signals in the buffer unit 900 may be transferred to an image processing unit (not shown) in a decoding sequence of the column decoder 710.

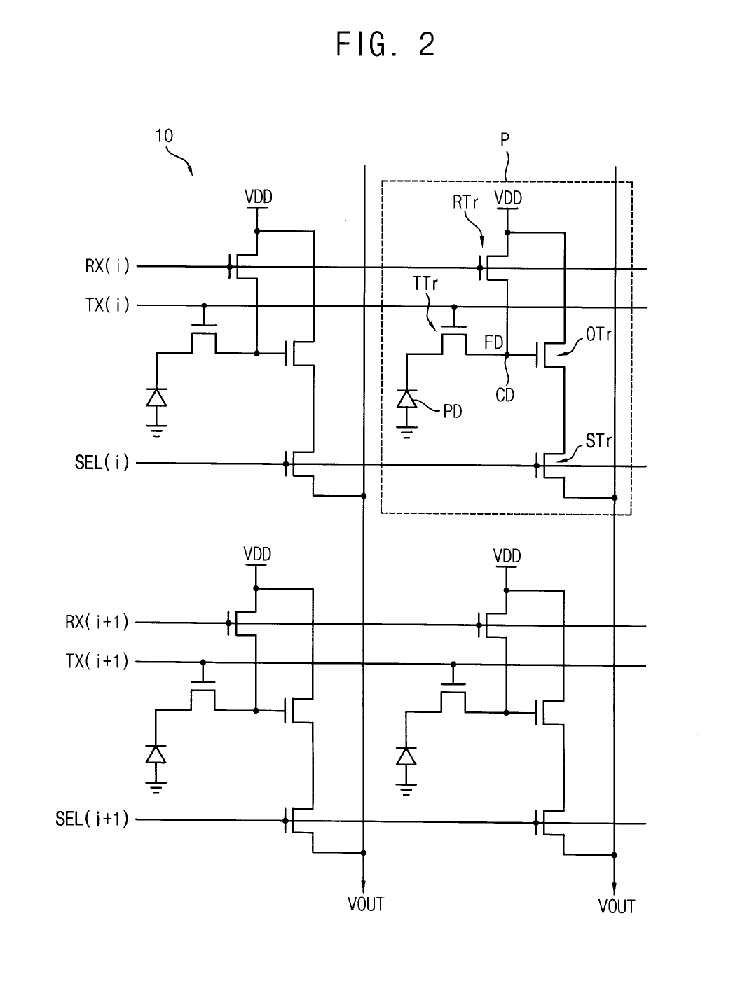

FIG. 2 is a circuit diagram showing the pixel array of the image sensor illustrated in FIG. 1 in accordance with an example embodiment of inventive concepts.

Referring to FIG. 2, the pixel array 500 may include a plurality of the unit pixels P in a two-dimensional matrix.

For example, the unit pixel P may include a photoelectric convertor PD generating photo charges corresponding to incident light, a transfer transistor TTr for transferring the photo charges in the photoelectric convertor PD to a charge detector CD and a reading device for detecting the photo charges in the charge detector CD to thereby read electrical signals of the corresponding unit pixel P from the charge detector CD. For example, the reading device may include a reset transistor RTr, an output transistor OTr and a selection transistor STr. Each of the reset transistor RTr, the output transistor OTr and the selection transistor STr may include a transistor comprising metal oxide silicon.

The configuration of the transistors may be varied according to the structures and purposes of the image sensor. While FIG. 2 illustrates that the unit pixel P includes one photoelectric convertor PD and four transistors TTR, RTr, OTr and STr, another number of the transistors may be used for the unit pixel P. For example, three transistors or five transistors may be allowable in the unit pixel P.

The photoelectric convertor PD may generate electron-hole pairs in response to the incident light and may collect the electrons and/or holes therein as the photo charges. For example, the photoelectric convertor PD may include a photo diode, a photo transistor, a photo gate, pinned photo diode (PPD) or combinations thereof. The photoelectric charges in the photoelectric convertor PD may be selectively transferred to the charge detector CD by the transfer transistor TTr and may be read as the electrical signal of the unit pixel P by the reading device having the reset transistor RTr, the output transistor OTr and the selection transistor STr. Thereafter, the electrical signal of the unit pixel P may be processed as an image signal.

The charge detector CD may include a floating diffusion area FD that may be arranged over the photoelectric convertor PD and adjacent to a top surface of the substrate. The charge detector CD may be doped with a plurality of n-type dopants and the photo charges in the photoelectric convertor PD may be transferred to and accumulated in the charge detector CD. In addition, the charge detector CD may be electrically connected to the output transistor OTr, to thereby control the operation of the output transistor OTr.

The transfer transistor TTr may selectively transfer the photo charges to the charge detector CD from the photoelectric convertor PD. In FIG. 2, the transfer transistor TTr may include a single MOS transistor and may be controlled via a transfer signal line TX(i), for an ith row.

The reset transistor RTr may be connected to a point between a power node (i.e., voltage source) Vdd and a floating diffusion area FD of the charge detector CD and may discharge the photo charges from the photo detector CD. For example, the reset transistor RTr may include a single transistor of which the source electrode may be connected to the floating diffusion area FD and of which the drain electrode may be connected to the power node Vdd. The reset transistor RTr may be driven by a reset signal through a reset signal line RX(i). When the reset transistor RTr may be operated by the reset signal, the voltage Vdd may be applied to the charge detector CD via the drain electrode of the reset transistor RTr, thereby resetting the charge detector CD.

The output transistor OTr may be connected to a static current source (not shown) that may be arranged in an exterior of the unit pixel P and may function as a source follower buffer amplifier together with the static current source. The output transistor OTr may be connected to the floating diffusion area FD, so that the voltage of the photo charges in the photo detector CD may be amplified by the output transistor OTr. The amplified voltage of the photo charges may be transformed to an output voltage Vout of the unit pixel P.

The selection transistor STr may be connected to a point between the output transistor OTr and an electrical ground, and may selectively read the output voltage Vout of the unit pixel P. At first, a row line to which a to-be-read unit pixel may be connected may be selected and then the output voltage Vout of the to-be-read unit pixel may be detected via a column line to which the to-be-read unit pixel may be connected by the selection transistor STr. The output voltage Vout may be processed as an image signal of the unit pixel P. For example, the selection transistor STr may be operated by a pixel selection signal that may be applied via a selection signal line SEL(i). When the selection transistor STr may be operated, the voltage Vdd, which may be connected to the drain electrode of the output transistor OTr, may be applied to the drain electrode of the selection transistor STr.

The transfer signal line TX(i), the reset signal line RX(i) and the pixel selection line SEL(i) may be repeatedly arranged along the row line of the pixel array 500 and each of the lines TX(i), RX(i) and SEL(i) may be connected a plurality of the unit pixels P along the same row line. Thus, the transfer signal, the reset signal and the pixel selection signal may be simultaneously applied to a number of the unit pixels P in the same row line of the pixel array 500.

The unit pixel P including the photoelectric convertor PD, the charge detector CD and the reading device may be formed on the semiconductor substrate in the following configurations and a plurality of the unit pixels P may be arranged in a matrix along the row and column lines.

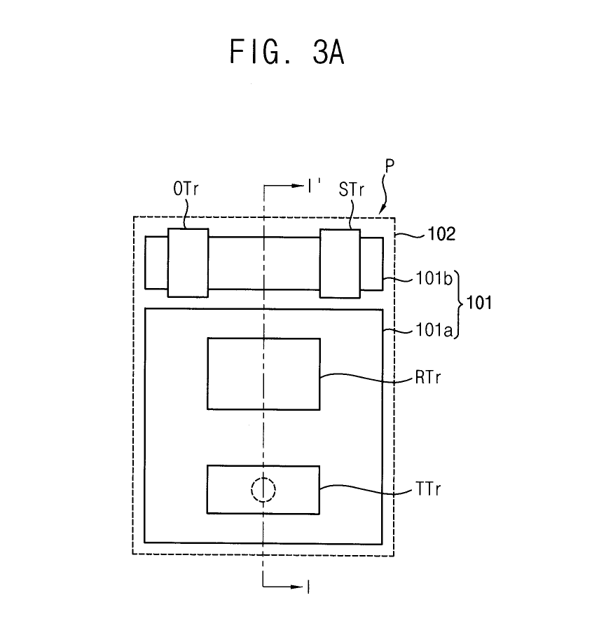

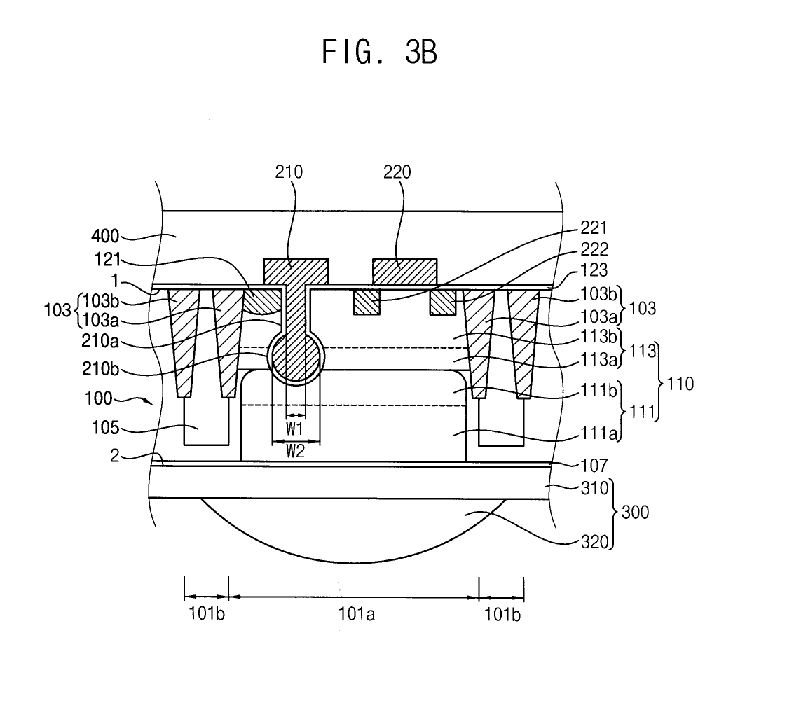

FIG. 3A is a plan view illustrating the unit pixel P of the image sensor 1000 shown in FIG. 1 and FIG. 3B is a cross sectional view cut along a line I-I′ of the unit pixel P shown in FIG. 3A.

Referring to FIGS. 3A and 3B, the unit pixel P of the pixel array 500 may include a photoelectric convertor 110 that may be arranged in an active region of a semiconductor substrate 100 together with first and second doping layers 111 and 113 and configured to generate photo charges corresponding to incident light, a transfer gate structure 210 of the transfer transistor TTr for transferring the photo charges to the charge detector CD and a reading gate structure 220 of the reading device for reading the electrical signals from the charge detector CD. A light transmittance unit 300 may be arranged on a lower portion of the substrate 100 for focusing the incident light to the photoelectric convertor 110 and a wiring structure 400 may be arranged on an upper portion of the substrate 100 for electrically communicating with the transfer gate structure 210 and the reading gate structure 220. The photoelectric convertor 110 and the photoelectric convertor PD may be the same.

For example, the substrate 100 may include a first surface 1 on which the wiring may be arranged and a second surface 2 opposite to the first surface 1 and on which the light transmittance unit 300 may be arranged. In FIGS. 3A-3B, the substrate 100 may include a bulk silicon substrate having a p-type well doped with a plurality of p-type dopants, a bulk silicon substrate on which a p-type epitaxial layer is formed and a p-type epitaxial body. A p-type epitaxial layer may be formed on a bulk silicon substrate and then the silicon substrate may be removed from the combination of the epitaxial layer and the substrate, thereby forming the p-type epitaxial body. In the contrary, the substrate 100 may also a bulk silicon substrate and/or epitaxial layer doped with n-type dopants.

A transmittance depth of the substrate 100 may be determined by the wavelength of the incident light that may be incident onto the light transmittance unit 300, thus the substrate 100 may have such a thickness that the incident light may sufficiently reach the photoelectric convertor PD in the substrate 100. Therefore, the thickness of the substrate 100 may be varied based on a desired wavelength range of the incident light. In FIGS. 3A-3B, the substrate 100 may have a thickness of about 0.5 μm to about 10 μm.

The substrate 100 may be include an active region 101 defined by a field region in which a device isolation layer 103 may be positioned. Operational units of the unit pixel P such as the photoelectric convertor PD and the transistors TTr, RTr, OTr and STr may be arranged on the active region 101 of the substrate 100 at every pixel. The device isolation layer 103 may be the boundaries of the active region 101, and the photoelectric convertors PD and the transistors TTr, RTr, OTr and STr in neighboring active regions 101 may be electrically insulated from each other by the device isolation layer 103.

In FIGS. 3A-3B, the active region 101 may include a first region 101a and a second region 101b, and the photoelectric convertor PD, the transfer transistor TTr and one of component transistors of the reading device may be arranged in the first region 101a and the rest of the component transistors of the reading device may be arranged in the second region 101b.

While an example embodiment discloses that the photoelectric convertor PD, the transfer transistor TTr and one of the reset transistor RTr, the output transistor OTr and the selection transistor STr may be arranged in the first region 101a and the rest of the reset transistor RTr, the output transistor OTr and the selection transistor STr may be arranged in the second region 101b, the arrangement of the photoelectric convertor PD and the transistors TTr, RTr, OTr and STr along the first and the second regions 101a and 10b may be variously modified according to the usage conditions and manufacturing selections of the image sensor 1000.

For example, the photoelectric convertor PD and the transfer transistor TTr may be arranged in the first region 101a and all of the transistors RTr, OTr and STr of the reading device may be arranged in the second region 101b.

The photoelectric convertor 110 may be positioned inside of the active region 101 of the substrate 100 and may generate the photo charges in proportional to the intensity of the incident light.

The substrate 100 may be doped with the p-type dopants and the photoelectric convertor 110 may include the first and the second doping layers 111 and 113 that may be vertically stacked inside of the p-doped substrate 100. The first doping layer may be doped with n-type dopants and the second doping layer may be doped with p-type dopants. Thus, the photoelectric convertor 110 may function as a photodiode having a p-n-p junction in the substrate 100. The photoelectric convertor 110 may include a pinned photodiode, a photo transistor and/or a photo gate.

The first doping layer 111 may include a first low concentration layer 111a having a relatively lower concentration of the n-type dopants and a first high concentration layer 111b arranged on the first low concentration layer 111a and having a relatively higher concentration of the n-type dopants. The concentration of the n-type dopants and the doping depth of the first low concentration layer 111a and the first high concentration layer 111b may be varied according to the manufacturing process conditions and design selections of the image sensor 1000.

The first doping layer 111 may generate the photo charges in response to the incident light. Thus, the first doping layer 111 may be arranged inside of the substrate 100 in such a configuration that the first doping layer 111 may be sufficiently apart from the first surface 1 of the substrate 100, thereby sufficiently preventing dark currents and white spots on the first surface of the substrate 100 that may be caused by surface defects of the substrate 100.

The second doping layer 113 may include a second low concentration layer 113a having a relatively lower concentration of the p-type dopants and a second high concentration layer 113b arranged on the second low concentration layer 113a and having a relatively higher concentration of the p-type dopants. The concentration of the p-type dopants and the doping depth of the second low concentration layer 113a and the second high concentration layer 113b may also be varied according to the manufacturing process conditions and design selections of the image sensor 1000.

The second low concentration layer 113a may function as a potential barrier between the first doping layer 111 and a floating diffusion area 121 that may be arranged adjacent to the first surface of the substrate 100. The potential barrier may be controlled by a transfer gate voltage that may be applied to the transfer gate structure 210. The second high concentration layer 113b may be interposed between the second low concentration layer 113a and the first surface 1 of the substrate 100, thereby preventing the dark currents on the first surface 1 of the substrate.

Electron-hole pairs (EHP) and the surface defects such as dangling bonds may be generated on the first surface 1 of the substrate 100 in the manufacturing process of the image sensor 1000. For example, the holes of the EHP may be grounded to the substrate 100 and the electrons of the EHP may be combined with the holes of the second high concentration layer 113b, thereby removing the EHP and preventing the dark currents on the first surface 1 of the substrate 100.

In addition, the second doping layer 113 may function as a channel layer for selectively transferring the photo charges by using the transfer gate voltage. Particularly, the depth of the second high concentration layer 113b may be varied according to the manufacturing process conditions of the image sensor 1000. While FIG. 3B illustrates that the second high concentration layer 113b is arranged under the floating diffusion area 121, the second high concentration layer 113b may also be arranged over the floating diffusion area 121.

The transfer gate structure 210 and the reading gate structure 220 may be arranged on the first surface 1 of the substrate 100. In FIGS. 3A-3B, the reading device may include the reset transistor RTr, the output transistor OTr and the selection transistor STr, and the reset transistor RTr may be arranged in the first region 101a while the output transistor OTr and the selection transistor STr of the reading device may be arranged in the second region 101b. Thus, the reading gate structure 220 in FIG. 3B may indicate a gate structure of the reset transistor RTr.

The transfer gate structure 210 may downwardly or vertically extend into the inside of the substrate 100 from the first surface 1 and may make contact with the photoelectric convertor 110. Thus, the photo charges in the photoelectric convertor 110 may be transferred to the floating diffusion area 121 by the transfer gate structure 210.

For example, the transfer gate structure 210 may include an upper structure 210a that may be adjacent to the first surface 1 of the substrate 100 and have a first width w1 and a lower structure 210b that may be adjacent to the photoelectric convertor 110 and have a second width w2 larger than the first width w1.

Thus, the transfer gate structure 210 may make contact with the photoelectric convertor 110 at a larger surface area, thus the length of an effective channel of the transfer transistor TTr may be increased. Therefore, the transfer efficiency of the photo charges may be sufficiently increased as much as the increased surface area of lower structure 210b of the transfer gate structure 210. Further, the upper structure 210a of the transfer gate structure 210 may be downsized around the first surface 1 of the substrate 100, the neighboring transfer gate structures 210 may be sufficiently spaced apart even though the active region 101 may be downsized. Therefore, an integration degree of the image sensor 1000 may be increased without any deterioration of the length of the effective channel of the transfer gate structure 210.

That is, when the active region 101 and the unit pixel P may be downsized so as to increase the degree of integration, the upper structure 210a of the transfer gate structure 210 may just be downsized while the lower structure 210b of the transfer gate structure 210 may be upsized or at least maintained without any size reduction, thereby preventing the short channel effect at the transfer gate structure 210 in spite of the size reduction of the unit pixel P. As a result, although the size of the image sensor 1000 may be reduced and the degree of integration of the images sensor may be increased, the transfer efficiency of the transfer transistor may not be deteriorated to thereby prevent the after-images of the image sensor.

In FIGS. 3A-3B, the upper structure 210a may be shaped into a pillar having the first width w1 and the lower structure 210b may be shaped into a round bottom flask having a diameter of the second width w2. Thus, the channel length of the transfer gate structure 210 may be increased as much as the enlarged surface area of the lower structure 210b, thereby preventing the short channel effect at the transfer gate structure 210.

While FIGS. 3A-3B illustrate that the lower structure 210b may make partial contact with the first doping layer 111, other arrangements would be allowable to the lower structure 210b according to the relative position of the transfer gate structure 210 and the photoelectric convertor 110. For example, the lower structure 210b may make partial contact with the second low concentration layer 113a or may be positioned in the second high concentration layer 113b.

In addition, other modifications of the shape and configurations would be allowable to the transfer gate structure 210 as long as the surface area of the lower structure 210b may be enlarged and the line width of the upper structure 210a may be reduced.

The transfer gate structure 210 may include a doped polysilicon pattern doped with n-type dopants and a metal silicide pattern in which a metal layer or a metal compound layer may be stacked on the doped polysilicon pattern.

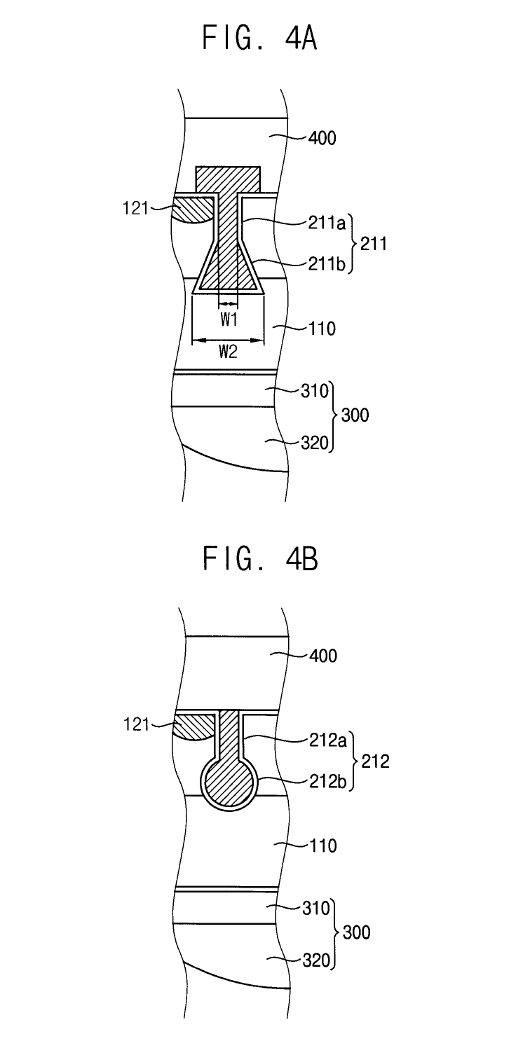

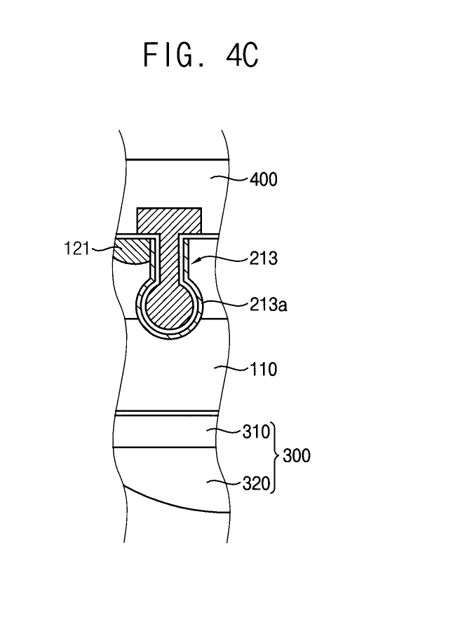

FIGS. 4A to 4C are cross-sectional views illustrating modified transfer gate structure of the unit pixel shown in FIG. 3B in accordance with an example embodiment of inventive concepts.

Referring to FIG. 4A, a first modification 211 of the transfer gate structure 210 may include a first modified upper structure 211a shaped into a pillar and a first modified lower structure 211b shaped into an Erlenmeyer flask shape having a slanted side and a flat bottom in parallel with the photoelectric convertor 110. Thus, the first modified lower structure 211b may have the second width w2 larger than the first width w1 of the first modified upper structure 211a, so that the lower portion of the first modification 211 may be enlarged as compared with the upper portion thereof. In addition, since the flat bottom of the first modified lower structure 211b may be in parallel with the photoelectric convertor 110, the photo charges in the photoelectric convertor 110 may be more efficiently transferred to the floating diffusion area 121.

Referring to FIG. 4B, a second modification 212 of the transfer gate structure 210 may include a second modified upper structure 212a that may be shaped into a pillar and may be buried in the substrate 100 and a second modified lower structure 212b that may be shaped into a round bottom flask and may be connected to the second modified upper structure 212a.

That is, the second modification 212 of the transfer gate structure 210 may be provided as a buried structure in the substrate 100, thus an overall height of the image sensor 1000 may be reduced.

Particularly, the buried structure of the second modification 212 may be shaped into a cylindrical ring and may make contact with a central portion of the photoelectric convertor 110. In case that the floating diffusion area 121 may be arranged at a central portion of the buried structure, the transfer efficiency of the photo charges may be increased together with the increase of the degree of integration of the image sensor 1000.

Referring to FIG. 4C, a third modification 213 of the transfer gate structure 210 may further include a local doping layer 213a covering an outer wall of the transfer gate structure 210. For example, the local doping layer 213a may be doped with p-type dopants at a concentration higher than that of the second doping layer 113, thus may accelerate the transfer of the photo charges to the floating diffusion area 121 from the first doping layer 111 that may be doped with n-type dopants.

The floating diffusion area 121 may receive the photo charges via the transfer gate structure 210 and the photo charges in the floating diffusion area 121 may be detected as an electrical signal that may be processed as an image signal of the unit pixel P. The floating diffusion area 121 may be doped with n-type dopants and be arranged over the second high concentration layer 113b that may be doped with p-type dopants. The floating diffusion area 121 may be arranged at every unit pixel in the active region 101 adjacent to the first surface 1 of the substrate 100 and may be vertically spaced apart from the photoelectric convertor 110.

Thus, the transfer gate structure 210 may control the electrical voltage of the second doping layer 113 doped with p-type dopants and interposed between the first doping layer 111 and the floating diffusion area 121, both of which may be doped with n-type dopants, and may transfer the photo charges to the floating diffusion area 121 from the photoelectric convertor 110 via the second doping layer 113. Therefore, the second doping layer 113 may function as a channel layer through which the photo charges may be transferred.

The reading gate structure 220 may function as a gate electrode of the reading device. For example, impurities may be implanted onto the second high concentration layer 113b adjacent to the reading gate structure 220, thereby forming source and drain areas 221 and 222 at a surface area of the second high concentration layer 113b around the reading gate structure 220. Thus, the reading device may be formed on the active region 101 of the substrate 100.

The reading gate structure 220 may include one of the gate electrodes of the reset transistor RTr for discharging the floating diffusion area 121, the output transistor OTr for amplifying the electrical signal detected from the floating diffusion area 121 and the selection transistor STr for reading the amplified signal as an output voltage of the unit pixel P selected by the selection signal.

Like the transfer gate structure 210, the reading gate structure 220 may include a polysilicon pattern and a metal silicide pattern having the polysilicon pattern and the metal pattern stacked on the polysilicon pattern. Source and drain areas 221 and 222 may be implanted with n-type or p-type dopants, to thereby form the source and the drain electrodes of the reading device.

A gate insulation layer 123 may be provided between the substrate 100 and the transfer and the reading gate structures 210 and 220, thus the gate structures 210 and 220 may be electrically insulated from the substrate 100. For example, the insulation layer 123 may include a nitride layer or an oxide layer.

The first region 101a of the active region 101 may be defined by a first device isolation layer 103a and the second region 101b adjacent to the first region 101a may be defined by the first device isolation layer 103a and a second device isolation layer 103b. As described above, the photoelectric convertor 110 and one component transistor of the reading device may be arranged on the first region 101a and the remaining transistors of the reading device may be arranged on the second region 101b.

In FIGS. 3A-3B, the device isolation layer 103 may include an insulation layer experiencing a shallow trench process (STI). The device isolation layer 103 may include an oxide pattern or a nitride pattern.

A separation well 105 may be further provided with the image sensor 1000. The separation well 105 may be interposed between the neighboring photoelectric convertors 110, to thereby prevent a cross talk between the neighboring unit pixels P. The separation well 105 may be arranged deeper than the device isolation layer 103, so that the bottom of the separation well 105 may be positioned under the bottom of the device isolation layer 103 in the substrate 100. Particularly, the separation well 105 may be equal to or greater than the depth of the photoelectric convertor 110 in the substrate 100, thereby efficiently preventing the cross talk between the neighboring unit pixels P.

For example, the depth of the separation well 105 may be substantially equal to the thickness of the substrate 100. Alternatively, no separation well may be provided with the unit pixel P. In such a case, the device isolation layer 103 may be formed to have such a depth that the neighboring unit pixels P may be sufficiently prevented from the cross talk by the device isolation layer 103.

In addition, a rear doping layer 107 may be further provided in the substrate 100 adjacent to the second surface 2 rather than the first surface 1. For example, the rear doping layer 107 may be doped with p-type dopants such as boron (B) at a concentration higher than that of the epitaxial layer on the substrate 100. Various surface defects, such as dangling bonds and defects caused by an etching stress, and a depletion well caused by an interface trap may be sufficiently prevented on the second surface 2 of the substrate 100 by the rear doping layer 107. Further, the rear doping layer 107 may function as a barrier layer for preventing the charges on the second face 2 from penetrating into the photoelectric convertor 110, thereby preventing the dark currents on the second surface 2 of the substrate 100.

The light transmittance unit 300 may be arranged on the second surface 2 of the substrate 100 so as to focus the incident light to the photoelectric convertor 110. When the incident light may reach the photoelectric convertor 110 through the light transmittance unit 300, the photo charges may be accumulated in the first doping layer 111 of the photoelectric convertor 110.

For example, the light transmittance unit 300 may include a color filter 310 arranged on the second surface 2 of the substrate 100 and a micro lens 320 arranged on the color filter 310.

The color filter 310 may be arranged on the second surface 2 of the substrate 100 correspondently to the photoelectric convertor 110 in such a way that the color filter 310 may be optically aligned with the photoelectric convertor 110. The color filter 310 may be provided with every unit pixel P, thus a plurality of the color filters 310 may be arranged on the second surface 2 of the substrate 100 in a matrix (referred to as color filter array). For example, the color filter array may include a Bayer filter pattern having a red filter, a green filter and/or a blue filter, so that the color filter 310 may include one of the red, green and blue filters of the Bayer filter pattern. Alternatively, the color filter array may include yellow filters, magenta filters, and/or cyan filters, so that the color filter 310 may include one of the yellow, magenta or cyan filter. The color filter array may also include a white filter.

The micro lens 320 may be arranged on the color filter 310 correspondently to the photoelectric convertor 110 in such a way that the micro lens 320 may be optically aligned with the photoelectric convertor 110 and to the color filter 310, respectively. The micro lens 320 may control the light path of the incident light, so that the incident light entering the micro lens 320 may be focused onto the photoelectric convertor 110. The micro lens 320 may also be provided with every unit pixel P, thus a plurality of the micro lenses 320 may be arranged on the second surface 2 in a matrix (referred to as micro lens array).

In an example embodiment, an anti-reflection layer (not shown) may be further arranged between the rear doping layer 107 and the color filter 310, thereby preventing the incident light from being reflected from the second surface 2 of the substrate 100. In the present example embodiment, the anti-reflection layer may include a multilayer in which material layers having different refractive indices may be alternately stacked. The greater the stack number of the material layers, the more the transmittance of the incident light to the photoelectric convertor 110 together with minimal reflection from the incident light at the second surface 2 of the substrate 100.

In FIG. 3B, the incident light may be inputted to the photoelectric convertor 110 from a rear portion or a back side of the substrate 100 and the transfer and the reading gate structures 210 and 220 may be arranged on a front portion or a front side of the substrate 100, thus the image sensor 1000 may be configured to a back side illumination (BIS) configuration. However, inventive concepts may also be applied to any other image sensors as well as the BIS type image sensor as long as the transfer gate structure may extend vertically into the substrate and the photo charges of the photoelectric convertor inside of the substrate may be transferred by the transfer gate transfer structure.

The wiring structure 400 may be arranged on the front side of the substrate 100 and may be electrically connected to the transfer gate structure 210 and the reading gate structure 220.

For example, the wiring structure 400 may include an interconnector (not shown) such as a contact and a plug penetrating through a number of insulation interlayers and a wiring line (not shown) interposed between the insulation interlayers and making contact with the interconnector. Thus, the wiring line may be electrically connected to the transfer and the reading gate structures 210 and 220 through the interconnector.

The driving signal may be applied to the transfer and the reading gate structures 210 and 220 via the wiring structure 400 and the output voltage Vout detected by the reading device may be transferred to the second signal unit 700 via the wiring structure 400.

According to some example embodiments of inventive concepts, the upper portion of the transfer gate structure 210 may be downsized in consideration of the size reduction of the image sensor 1000. However, the lower portion of the transfer gate structure 210 may be upsized in spite of the size reduction of the image sensor 1000. Therefore, although the active region 101 and the unit pixel P may be downsized so as to increase the degree of integration of the image sensor 1000, the lower portion of the transfer gate structure 210 may be upsized or at least maintained without any size reduction, thereby preventing the short channel effect at the transfer gate structure 210 in spite of the size reduction of the unit pixel P. As a result, although the size of the image sensor 1000 may be reduced and the degree of integration of the images sensor may be increased, the transfer efficiency of the transfer transistor may not be deteriorated to thereby prevent the after-images of the image sensor.

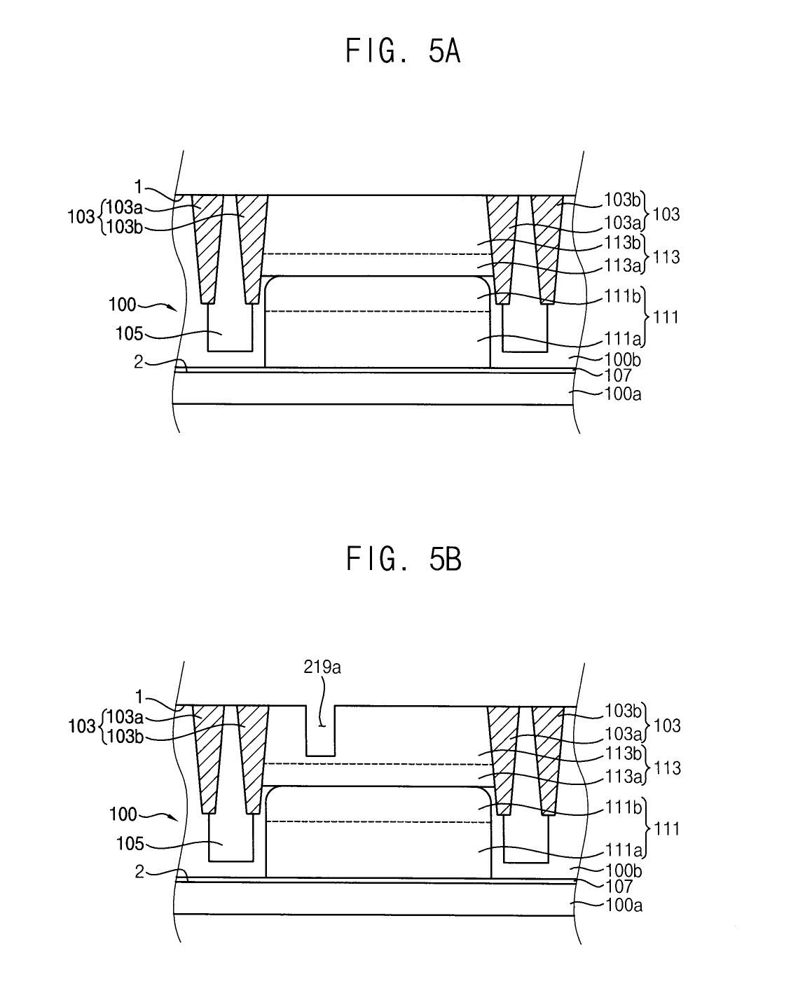

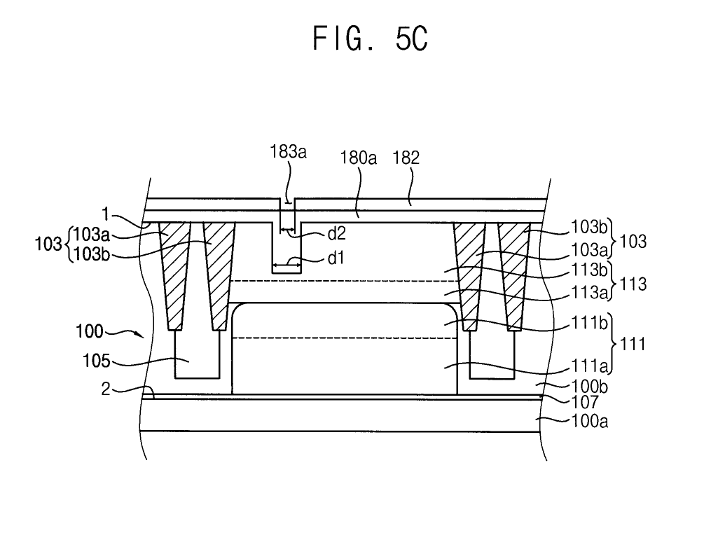

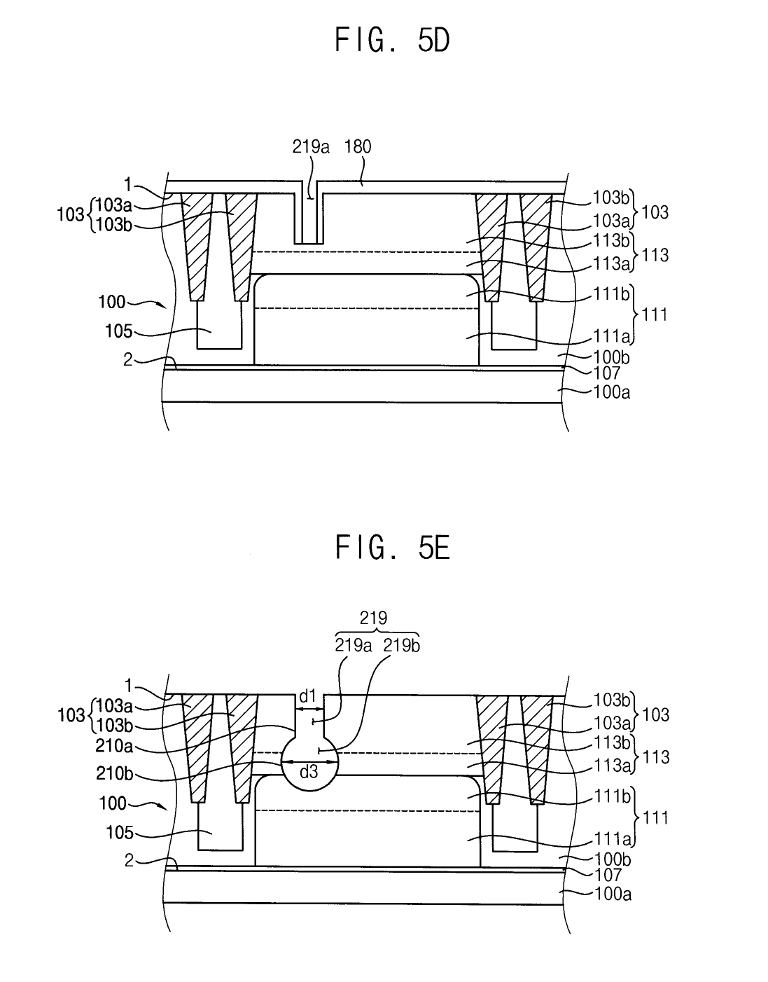

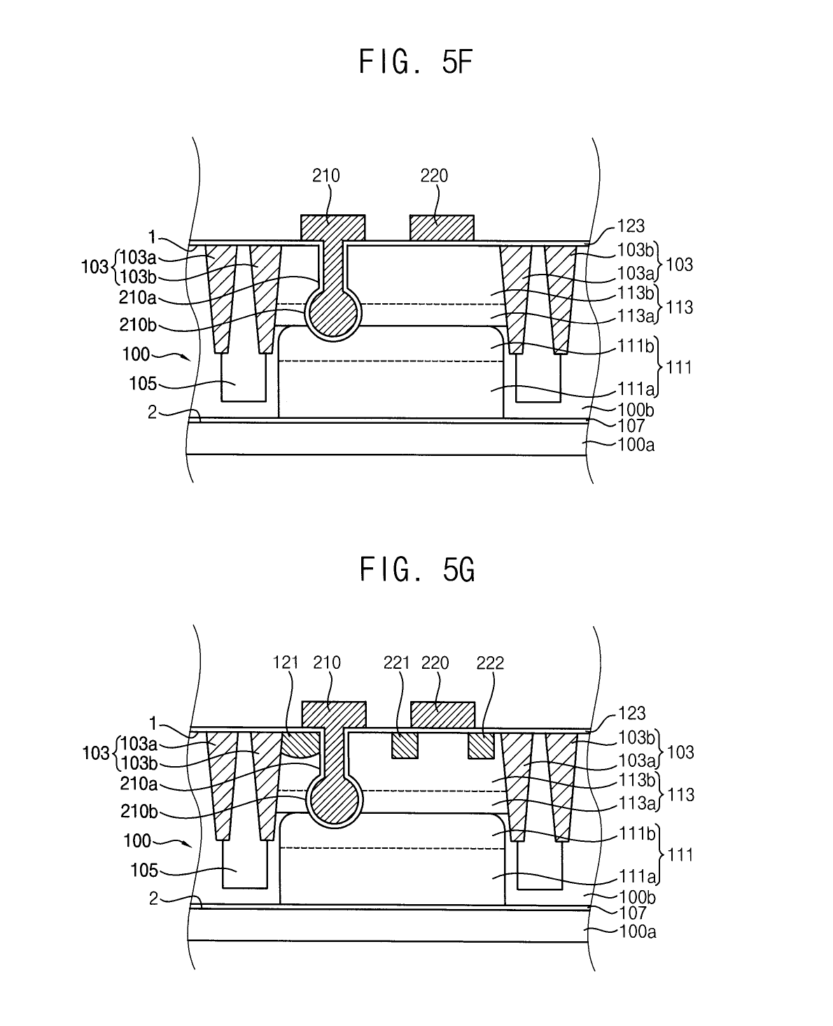

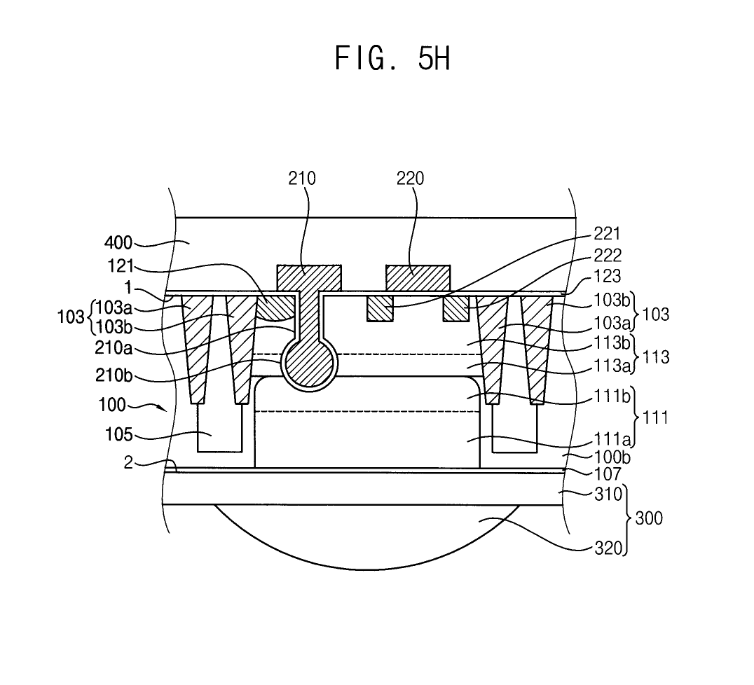

Hereinafter, a method of manufacturing the image sensor shown in FIGS. 1, 3A and 3B will be described in detail with reference to FIGS. 5A to 5H. FIGS. 5A to 5H are cross sectional views illustrating the processing steps for the method of manufacturing the image sensor shown in FIGS. 1, 3A and 3B.

Referring to FIGS. 1, 3A, 3B and 5A, the photoelectric convertor 110 may be formed on the active region 101 that may be defined by the device isolation layer 103 in the semiconductor substrate 100.

For example, the substrate 100 may include a p-type bulk substrate 100a having the first surface 1 and the second surface 2 opposite to the first surface 1 and a p-type epitaxial layer 100b that may be formed in the substrate 100 by an epitaxial process around a rear surface of the substrate 100. The first surface 1 of the substrate may correspond to an upper surface of the substrate 100 and the p-type epitaxial layer 100b may be spaced apart from the rear surface of the substrate 100, and thus the second surface 2 of the substrate 100 may correspond to a bottom surface of the epitaxial layer 100b. In a modified example, a p-type well (not shown) may be formed in the p-type bulk substrate 100a in place of the p-type epitaxial layer 101b. In another modified example, the substrate 100 may include a silicon-on-insulator (SOI) substrate.

In addition, p-type dopants may be further doped into the p-type epitaxial layer 100b, thereby forming the rear doping layer 107 at bottom surface portions of the epitaxial layer 100b. Thus, the rear doping layer 107 may be formed inside the substrate 100 closer to the second surface 2 than the first surface 1. Particularly, the concentration of the dopants at the rear doping layer 107 may be greater than that of the epitaxial layer 100b because the p-type dopants may be additionally implanted onto the epitaxial layer 100b. For those reasons, the rear doping layer may prevent the dark currents on the second surface 2.

Then, the device isolation layer 103 may be formed in the substrate 100 to thereby define the active region 101. The device isolation layer 103 may be formed into a first device isolation layer 103a defining the first region 101a and a second device isolation layer 103b defining the second region 101b together with the first device isolation layer 103a. The device isolation layer 103 may be formed in the substrate 100 by a shallow-trench isolation (STI) process or a local oxidation of silicon (LOCOS) process.

After forming the device isolation layer 103, p-type dopants may be further implanted into the substrate 100 to thereby form the separation well 105 in the substrate 100 so as to protect the cross talk between the neighboring pixels P. The separation well 105 may be formed to have a depth greater than that of the device isolation layer 103, so that the bottom of the separation well 105 may be positioned under the bottom of the device isolation layer 103. Particularly, the depth of the separation well 105 may be equal to or greater than that of the photoelectric convertor 110 so as to sufficiently prevent the cross talk between the neighboring pixels P. In a modified example embodiment, the separation well 105 may extend to the rear doping layer 107, thus the separation well 105 may be connected to the rear doping layer 107 in the substrate 100.

A first mask pattern (not shown) may be formed on the substrate 100 in such a way that the first region 101a may be exposed through the first mask pattern. Then, n-type dopants and p-type dopants may be sequentially implanted onto the substrate 100 using the first mask pattern as an ion implantation mask, thereby forming the first doping layer 111 doped with the n-type dopants and the second doping layer 113 doped with the p-type dopants.

The n-type dopants may be implanted into the epitaxial layer 100b at a first concentration using the first mask pattern as an ion implantation mask, thereby forming the first low concentration layer 111a. Then, the n-type dopants may be implanted again into the epitaxial layer 100b at a second concentration higher than the first concentration, thereby forming the first high concentration layer 111b on the first low concentration layer 111a.

In the same way, the p-type dopants may be implanted into the epitaxial layer 100b at a first concentration using the first mask pattern as an ion implantation mask, thereby forming the second low concentration layer 113a on the first high concentration layer 111b. Then, the p-type dopants may be implanted again into the epitaxial layer 100b at a second concentration higher than the first concentration, thereby forming the second high concentration layer 113b on the second low concentration layer 113a.

Thus, the first doping layer 111 doped with n-type dopants may be formed deep inside the epitaxial layer 100b and the second doping layer 113 doped with p-type dopants may be formed on the first doping layer 111. Therefore, the first and the second doping layers 111 and 113 may be formed in the epitaxial layer 100b. The second low concentration layer 113a may function as a potential barrier and the second high concentration layer 113b may function as an impurity doped area for the transfer and reading device of the image sensor 1000.

Referring to FIGS. 1, 3A, 3B and 5B, a first trench 219a may be formed on the first surface 1 of the substrate 100.

For example, a second mask pattern (not illustrated) may be formed on the first surface 1 of the substrate 100 in such a way that the first region 101a may be partially exposed through the second mask pattern. Then, the first region 101a of the substrate 100 may be removed by an anisotropic etching process using the second mask pattern as an etching mask, thereby forming the first trench 219a in the first region 101a of the substrate 100.

A bottom of the first trench 219a may reach the second doping layer 113 or the first doping layer 111 in view of operation conditions and characteristics of the image sensor 1000.

Referring to FIGS. 1, 3A, 3B and 5C, a sacrificial layer 180a may be formed on the substrate 100 in such a way that the first trench 219a may be filled with the sacrificial layer 180 and an upper surface of the sacrificial layer 180 may be planarized. Then, a third mask pattern 182 may be formed on the sacrificial layer 180a in such a way that the sacrificial layer 180a corresponding to the first trench 219a may be exposed through the third mask pattern 182.

The sacrificial layer 180a may have sufficient gap-fill characteristics for filling up the first trench 219a and have sufficient etching selectivity with respect to the third mask pattern 182. For example, the sacrificial layer 180a may include an oxide layer and a photoresist layer. Then, a third mask layer (not illustrated) may be formed on the sacrificial layer 180a and then may be partially removed by a photolithography process, to thereby form an opening 183 through which the sacrificial layer 180a corresponding to the first trench 219a may be exposed.

Particularly, the opening 183 may be formed in the third mask layer in such a configuration that a central line of the opening 183 may be aligned with a central axis of the first trench 219a and a width d2 of the opening 183 may be smaller than the width d1 of the first trench 219a. In FIG. 5C, the width d2 of the opening 183 may be about 80% to about 90% of the width d1 of the first trench 219a.

Referring to FIGS. 1, 3A, 3B and 5D, the sacrificial layer 180a may be partially removed from the substrate 100 by an anisotropic etching process using the third mask pattern 182 as an etching mask, until a bottom of the first trench 219a may be exposed through the opening 183, thereby forming a sacrificial pattern 180 on the substrate 100.

That is, a sidewall of the first trench 219a may be covered with the sacrificial pattern 180, and the bottom of the first trench 219a may be exposed through the sacrificial pattern 180. Thereafter, the third mask pattern 182 may be removed from the substrate 100.

Referring to FIGS. 1, 3A, 3B and 5E, the bottom of the first trench 219a may be further removed by an isotropic etching process using the sacrificial pattern 180 as an etching mask, thereby forming a second trench 219b communicating with the first trench 219a. The first and the second trenches 219a and 219b may constitute a transfer gate trench 219 in the first region 101a for forming the transfer gate structure 210.

Particularly, the isotropic etching process may be performed until the sacrificial pattern 180 may be sufficiently removed from the sidewall of the first trench 219a, so that the first trench 219a may be prevented from being stretched. That is, the isotropic etching process may be performed against the bottom of the first trench 219a, so that the second trench 219b may be formed under the first trench 219a continuously with the first trench 219a.

The second trench 219b may have the same width and depth due to the isotropic characteristics of the etching process. Therefore, the second trench 219b may be shaped into a sphere having a diameter or a width d3 greater than the width d1 of the first trench 219a.

The differentiation between the widths d1 and d3 of the first and the second trenches 219a and 219b may be determined by a thickness of the sacrificial pattern 180 covering the sidewall of the first trench 219a. Accordingly, the size of the second trench 219b may be controlled by the ratio of the width d1 of the first trench 219a and the width d2 of the opening 183.

Although not shown in figures, the second trench 219b may be modified into various shapes according to conditions and environments of the isotropic etching process such as the first modification 211 of the transfer gate structure 210 described in detail with reference to FIG. 4A.

Referring to FIGS. 1, 3A, 3B and 5F, a gate insulation layer 123 may be formed on the first surface 1 and on the sidewall and the bottom of the gate trench 219. Then, the transfer gate structure 210 may be formed in such a way that the gate trench 219 may be filled up with the transfer gate structure 210. In addition, the reading gate structure 220 may be formed on the first surface 1 in the first region 101a of the substrate 100.

For example, the gate insulation layer 123 may be formed on the active region 101 of the substrate 100 in conformal with the surface profile of the gate trench 219 by a chemical vapor deposition (CVD) process or an atomic layer deposition (ALD) process in view of step coverage. For example, the gate insulation layer 123 may comprise oxide, nitride and metal oxide having high dielectric constant.

Particularly, prior to the formation of the gate insulation layer 123, the p-type dopants may be further implanted onto the sidewall and the bottom of the gate trench 219 by an ion implantation process, thereby forming the local doping layer 213a described in detail with reference to FIG. 4C. In such a case, the ion implantation process may be controlled in such a way that the concentration of the p-type dopants in the local doping layer 213a may be greater than that of the second high concentration layer 113b. Therefore, the p-type dopants may be locally implanted around the gate trench 219 at a concentration higher than that of the second high concentration layer 113b, thereby forming the local doping layer 213a.

The local doping layer 213a may prevent the charges of the surface portions of substrate in the gate trench 219 from moving into the first doping layer 111, thereby preventing the dark current around the transfer gate structure 210 and increasing the transfer efficiency of the photo charges from the first doping layer 111 to the floating diffusion area 121.

Thereafter, a gate conductive layer (not shown) may be formed on the substrate 100 to a sufficient thickness to fill up the gate trench 219. Then, the gate conductive layer may be patterned into the transfer gate structure 210 and one of the reading gate structures 220 in the first region 101a and the rest of the reading gate structures (not shown) in the second region 101b.

The gate conductive layer may comprise doped polysilicon, a high conductive metal such as tungsten (W), titanium (Ti) and tantalum (Ta) or a metal silicide in which the high conductive metal may be stacked on the doped polysilicon and [symbol] .

In a modified example embodiment, the gate conductive layer may be planarized in such a way that the gate conductive layer may remain in the gate trench 291, thereby forming the second modification 212 of the transfer gate structure 210 may be formed in the gate trench 219 as the buried gate structure in the gate trench 291 as shown in FIG. 4B.

Referring to FIGS. 1, 3A, 3B and 5G, dopants may be implanted onto the active region 101 around the transfer gate structure 210 and around the reading gate structure 220, thereby forming the floating diffusion area 121 adjacent to the transfer gate structure 210 and the source and the drain areas 221 and 222 adjacent to the reading gate structure 220, respectively.

For example, a fourth mask pattern (not shown) may be formed on the substrate 100 in such a way that the active region 101 may be partially exposed through the fourth mask pattern around the floating diffusion area 121, and then n-type dopants may be implanted onto the partially exposed active region 101 using the fourth mask pattern as an ion implantation mask. Therefore, the floating diffusion area 121 may be formed at surface portions of the active region 101 adjacent to the transfer gate structure 210.

In case that the floating diffusion area 121 and the source/drain regions 221 and 222 may have the same electrical polarity, the fourth mask pattern may also expose the portion of the active region 101 around the reading gate structure 220 and the n-type dopants may also be implanted onto the exposed active region 101 around the reading gate structure 220, thereby forming the source/drain regions 221 and 222 simultaneously with the floating diffusion area 121.

In contrary, in case that the floating diffusion area 121 and the source/drain regions 221 and 222 may have different electrical polarity, the ion implantation process may be individually performed around the transfer gate structure 210 and the reading gate structure 220, respectively.

Referring to FIGS. 1, 3A, 3B and 5H, the wiring structure 400 may be formed on the first surface 1 of the substrate 100 and the light transmittance unit 300 may be formed on the second surface 2 of the substrate 100.

For example, insulation interlayers (not shown) may be formed on the first surface 1 of the substrate 100 with which the transfer gate structure 210 and the floating diffusion area 121 may be provided, and a plurality of metal wirings may be interposed between the insulation interlayers. The metal wirings may be connected with each other though interconnectors penetrating through the insulation interlayers. That is, the wiring structure 400 may include the metal wirings and the interconnectors in the insulation interlayers.

Thereafter, the p-type bulk substrate 100a may be cut off from the substrate 100, so that the second surface 2 may be exposed in such a configuration that the bottom surface of the epitaxial layer 100b and/or the doping layer 107 may be exposed. Then, the color filter 310 and the micro lens 320 may be formed on the second surface 2 of the substrate 100, thereby forming the light transmittance unit 300 on the second surface 2 of the substrate 100.

That is, the light transmittance unit 300 on the second surface 2 may be arranged opposite to the floating diffusion unit 121 around the first surface 1. Thus, the image sensor 1000 may be manufactured into a back-side illumination structure.

Since the color filter 310 and the micro lens 320 may correspond to every photoelectric convertor 110 of the unit pixel P, a plurality of color filters 310 may be arranged on the second surface as a color filter array and a plurality of the micro lenses 320 may be arranged on the second surface as a micro lens array.

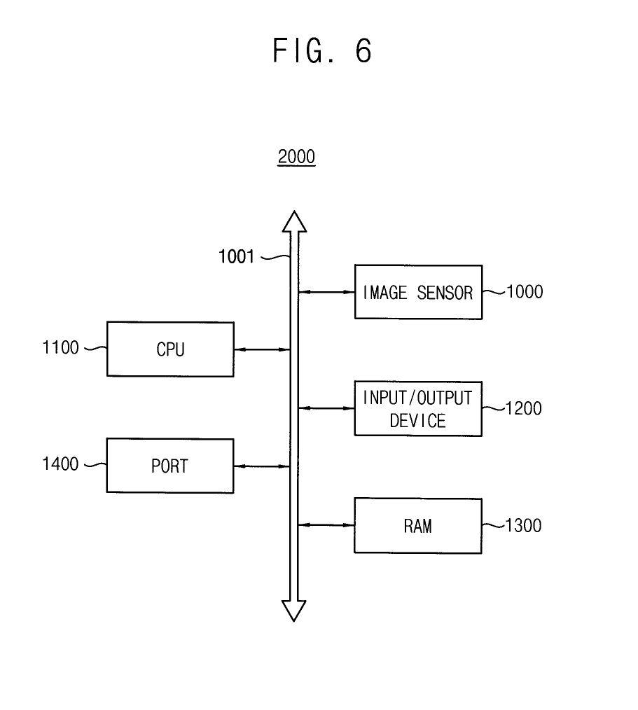

FIG. 6 is a block diagram showing an imaging apparatus including the image sensor shown in FIG. 1 in accordance with an example embodiment of inventive concepts. In FIG. 6, an image signal generated from the image sensor 1000 shown in FIG. 1 may be processed in the exemplarily imaging apparatus 2000.

Referring to FIG. 6, the imaging apparatus 2000 in accordance with an example embodiment of inventive concepts may include a central processing unit 1100 such as a microprocessor that may be electrically communicated with an input/output device 1200 through a bus line 1001. The image sensor 1000 may be electrically communicated with other elements or components through the bus line 1001 or other communication links. The imaging apparatus 2000 may also include a memory device 1300 such as a random access memory (RAM) device and/or port 1400 that may be electrically connected with the CPU 1100 through the bus line 1001.

The port 1400 may perform a data communication with various peripheral equipments, and thus may be connected with a sound card, a video card, an external memory card and various universal serial bus (USB) devices.

The image sensor 1000 may be mounted on a single mother board together with the CPU 1100, the memory device 1300, a digital signal processing device (DSP) and/or a microprocessor.

The imaging apparatus 2000 may be applied to an imaging module for a computer system, a digital camera, a scanner, a digital clock, a navigation system, a video phone, an auto-focusing system, a tracking system, a remote monitoring system and/or an image stabilization system.

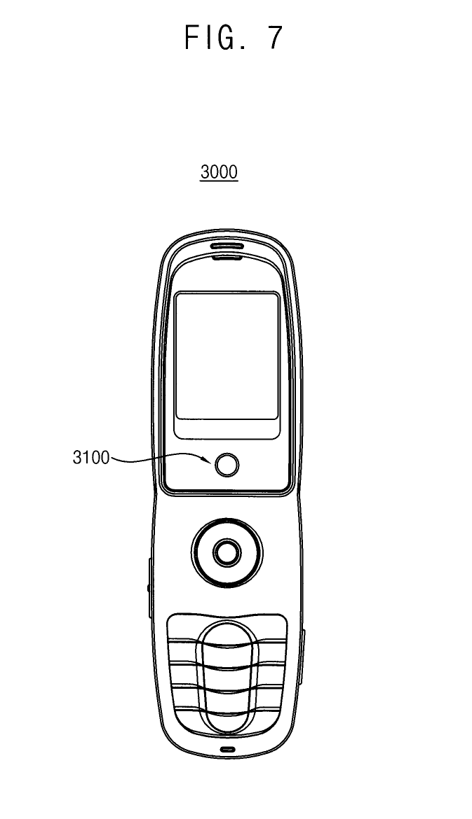

FIG. 7 is a perspective view illustrating an electronic system including the imaging apparatus shown in FIG. 6 in accordance with an example embodiment of inventive concepts.

Referring to FIG. 7, the electronic system 3000 in accordance with an example embodiment of inventive concepts may include the imaging apparatus be described in detail with reference to FIG. 6 and a light guide 3100 for guiding an external light to the light transmittance unit 300 of the imaging apparatus.

The external light reflected from an object may be guided to the light transmittance unit 300 through the light guide 3100 of the electronic system 3000, and the guided light may generate photo charges at the photoelectric convertor 110. The photo charges may be transformed to the image of the object in the imaging apparatus 2000.

Although the electronic system 3000 may be downsized and have small inner space and the imaging apparatus may have higher resolutions, the image of the object may be sufficiently prevented from being deteriorated because the transfer gate structure due to the sufficient charge transfer of the photo charges from the photoelectric convertor to the floating diffusion area 121. The transfer gate structure 210 of the image sensor 1000 may have a sufficient effective channel length, thus the photo charges may be transferred to the floating diffusion area 121 with sufficient efficiency. Therefore, the electronic system 3000 may display the high revolution image of the object without any after-images despite the size reduction of the electronic system 3000.

For example, the electronic system 3000 may include a mobile phone, a digital camera, a digital camcorder, a personal digital assistant (PDA), a wireless phone, a laptop computer, an optical mouse, a facsimile and a copying machine.

Other systems may include the image sensor 1000 shown in FIG. 1. For example, the image sensor 1000 may be applied to a digital telescope, a scanner, an endoscope, a fingerprint scanner, various digital toys and game players, a home robot and an IT-vehicle convergence.

According to example embodiments, the upper portion of the transfer gate structure may be downsized in view of the size reduction of the image sensor. However, the lower portion of the transfer gate structure, which may be connected to the photoelectric convertor, may be upsized in spite of the size reduction of the image sensor. Therefore, although the active region and the unit pixel P may be downsized so as to increase the degree of integration of the image sensor, the lower portion of the transfer gate structure may be upsized or at least maintained without any size reduction, thereby preventing the short channel effect at the transfer gate structure in spite of the size reduction of the unit pixel. As a result, although the size of the image sensor may be reduced and the degree of integration of the images sensor may be increased, the transfer efficiency of the transfer transistor may not be deteriorated to thereby prevent the after-images of the image sensor.

Example embodiments may be applied to various imaging apparatuses and electronic systems including the image sensor in which the transfer gate structure may be provided with vertical shape in the substrate. Particularly, the image sensor may be applied to a back-side illuminated CMOS sensor for increasing the image quality.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of inventive concepts. Accordingly, all such modifications are intended to be included within the scope of inventive concepts as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. An image sensor comprising:
a photoelectric convertor in an active region of a substrate, the photoelectric converter configured to generate photo charges corresponding to incident light;
a floating diffusion area over the photoelectric convertor and adjacent to a first surface of the substrate, the floating diffusion area configured to receive the photo charges;
a transfer transistor having a transfer gate structure, the transfer transistor configured to transfer the photo charges to the floating diffusion area from the photoelectric convertor, the transfer gate structure having a narrow upper structure and a broad lower structure having a greater width than the upper structure, the upper structure extending from the first surface of the substrate to the lower structure; and
a reading device on the first surface of the substrate, the reading device configured to detect the photo charges from the floating diffusion area and output electrical signals corresponding to the photo charges.

2. The image sensor of claim 1, wherein
the photoelectric convertor includes a first doping layer having a first plurality of n-type dopants and a second doping layer having a first plurality of p-type dopants, and
the floating diffusion area includes a second plurality of n-type dopants.

3. The image sensor of claim 2, wherein
the first doping layer includes a first low concentration layer and a first high concentration layer, the first high concentration layer having a higher concentration of n-type dopants than the first low concentration layer, and
the second doping layer includes a second low concentration layer and a second high concentration layer, the second high concentration layer having a higher concentration of p-type dopants than the second low concentration layer.

4. The image sensor of claim 1, wherein the upper structure is adjacent to the floating diffusion area and the lower structure is connected to the photoelectric convertor.

5. The image sensor of claim 4, wherein the lower structure is one of a spherical flask shape and an Erlenmeyer flask shape.

6. The image sensor of claim 1, wherein a top surface of the transfer gate structure is coplanar with the first surface of the substrate and buried in the substrate.

7. The image sensor of claim 2, further comprising:
a local doping layer in the substrate, the local doping layer enclosing the transfer gate structure, the local doping layer having a second plurality of p-type dopants, and the local doping layer having a higher concentration of p-type dopants than the second doping layer.

8. The image sensor of claim 1, wherein the active region of the substrate includes a first region and a second region, the first region including the photoelectric convertor and the transfer transistor, the second region being adjacent to the first region, at least a portion of the reading device being in the second region.

9. The image sensor of claim 8, wherein the reading device includes,
a reset transistor configured to discharge the floating diffusion area;
an output transistor configured to amplify a voltage of the floating diffusion area and output the amplified voltage as an output voltage of a unit pixel; and
a selection transistor configured to select the unit pixel in response to a selection signal and transfer the output voltage,
one of the reset, the output and the selection transistors is in the first region and the remaining transistors of the reading device are in the second region.

10. The image sensor of claim 1, further comprising:
a rear doping layer having a plurality of p-type dopants, the rear doping layer being adjacent to a second surface of the substrate, the second surface being opposite to the first surface.

11. The image sensor of claim 10, further comprising:
a light transmittance unit on the second surface of the substrate, the light transmittance unit corresponding to the photoelectric convertor, the light transmittance unit configured to focus the incident light to the photoelectric convertor.

12. The image sensor of claim 11, wherein the light transmittance unit includes a micro lens configured to focus the incident light to the photoelectric convertor and a color filter under the micro lens.

13. An image sensor comprising:
a pixel array having a plurality of unit pixels in a matrix, the unit pixels configured to generate electrical signals from incident light;
a first signal unit configured to apply a driving signal to each of the unit pixels in the pixel array through a plurality of row lines of the matrix;
a second signal unit configured to detect the electrical signals of each unit pixel through a plurality of column lines of the matrix; and
a timing signal generator configured to generate a timing signal for selectively controlling the row lines and the column lines,
wherein at least one of the unit pixels includes,
a photoelectric convertor in an active region of a substrate, the photoelectric converter configured to generate photo charges corresponding to incident light,
a floating diffusion area over the photoelectric convertor and adjacent to a first surface of the substrate, the floating diffusion area configured to receive the photo charges,
a transfer transistor having a transfer gate structure, the transfer transistor configured to transfer the photo charges to the floating diffusion area from the photoelectric convertor, the transfer gate structure having a narrow upper structure and a broad lower structure having a greater width than the upper structure, the upper structure extending from the first surface of the substrate to the lower structure; and
a reading device on the first surface of the substrate, the reading device configured to detect the photo charges from the floating diffusion area and output electrical signals corresponding to the photo charges.

14. The image sensor of claim 13, wherein
the first signal unit includes a row decoder and a row driver, and
the second signal unit includes a column decoder, a correlated double sampler and an analogue-to-digital converter (ADC).

15. The image sensor of claim 14, further comprising:
a buffer unit configured to receive a plurality of image signals corresponding to the electrical signals and process the image signals in a decoding sequence of the column decoder.

16. An image sensor comprising:
a substrate;
a photoelectric converter in the substrate, the photoelectric converter configured to generate charges based on incident light; and
a transfer transistor configured to transfer the generated charges, the transfer transistor having a transfer gate structure, the transfer gate structure including an upper portion and a lower portion, the upper portion extending from an upper surface of the substrate to the lower portion in a direction towards a lower surface of the substrate, a width of the lower portion being greater than a width of the upper portion.

17. The image sensor of claim 16, wherein the photoelectric converter includes a first doping layer and a second doping layer, the second doping layer including a first concentration layer and a second concentration layer, a concentration of first-type dopants in the second concentration layer being higher than a concentration of first-type dopants in the first concentration layer, the second concentration layer being between the first concentration layer and the upper surface of the substrate.

18. The image sensor of claim 17, wherein the first doping layer includes a third concentration layer and a fourth concentration layer, a concentration of second-type dopants in the fourth concentration layer being higher than a concentration of second-type dopants in the third concentration layer, the third concentration layer being between the fourth concentration layer and the lower surface of the substrate.

19. The image sensor of claim 18, wherein the first-type dopants are p-type dopants and the second-type dopants are n-type dopants.

20. The image sensor of claim 16, further comprising:
a floating diffusion area in the substrate, on the photoelectric converter and adjacent to the upper surface of the substrate, the floating diffusion area configured to receive the generated charges from the transfer transistor; and
a read device configured to output the charges received by the floating diffusion area.
